(19) United States
(12) Patent Application Publication
(10) Pub. No.: US 2005/0277244 A1
(43) Pub. Date: Dec. 15, 2005

(54) Method for fastening microtool components to objects

(76) Inventors: Norbert Galster, Rupperswil (CH); Ignaz Egger, Giswil (CH); Philippe Steiert, Greppen (CH); Gerhard Palm, Sickte (DE)

Correspondence Address: RANKIN, HILL, PORTER & CLARK LLP, 4080 ERIE STREET, WILLOUGHBY, OH, 44094-7836, US

(21) Appl. No.: 10/521,880

(22) PCT Filed: Nov. 21, 2002
(86) PCT No.: PCT/CH02/00631

§ 371 Date: Jan. 21, 2005

Related U.S. Application Data
(60) Provisional application No. 60/397,818, filed on Jul. 23, 2002.

(51) Int. Cl. H01L 21/8238

(52) U.S. Cl. 438/202

(57) ABSTRACT

A microtool for embossing structures into a substrate is fastened to an object, such as a press plate, by sintering, preferably pressure sintering. An insight underlying the invention is the fact that such a sintering or pressure sintering method provides a sufficiently reliable, strong, heat conducting and/or dimensionally stable connection, even for a hot embossing process, where at elevated temperatures, pressures of 10-300 bar and tensile forces of up to 100-200 bar may act upon the connection, and where a dimensional stability of down to the micrometer scale may be required. According to a preferred embodiment, the forming temperature of a pressure sintered connection equals the embossing temperature, i.e. the working temperature of the tool.

### FIELD OF THE INVENTION

The invention is in the field of microtools, especially for producing, by embossing, imprinting or deep-drawing fine structures, especially structures in substrates for high-density interconnects.

### BACKGROUND OF THE INVENTION

Microtools for embossing, imprinting or deep-drawing structures into elements are widely used in various technical fields. Increasing miniaturization of elements to be structured leads to increased miniaturization of the microtools.

Tools for embossing (or imprinting or deep-drawing) often comprise a—maybe relatively thin—microtool component comprising the embossing (or imprinting etc.) surface and further comprising an object to which this microtool component is fastened, such as a substrate for providing mechanical stability, or a spacer plate etc.

For microtool assembly processes either glueing or soldering techniques have been used so far. Drawbacks of those methods are poor uniformity, low maximal operating temperatures and high induced stress.

Especially, if tool components of different materials are assembled there may be, at the working temperature of the tool, a deformation due to a bimetallic effect—especially if it is a tool for hot embossing. This is because usually the manufacturing temperature and the working temperature of the tool are not equal. Such a deformation is often not acceptable.

It is often desirable to have a whole array of microtools in order to enable mass production. A special category of problems arises where such an array of tools is used for embossing a thin layer-like element from both sides. In this case, the whole array of microtools has to be aligned with the respective counterparts with a high precision. For example, a tool comprising a plurality of microtools may be used for hot embossing fine structures used for High Density Interconnects (HDIs). A method for hot embossing HDIs and prefabricated products for HDIs using microtools is disclosed in WO 01/50825, the HDI production method and the microtool dimensions disclosed in this reference being incorporated herein by reference. As will become apparent from this disclosure, the fabrication of microvias requires there to be a precision of the order of magnitude of 1 μm.

### SUMMARY OF THE INVENTION

It is therefore an object of the invention to provide a method of connecting a microtool component to an object, which method overcomes drawbacks of prior art methods and which is especially suited for microtools for hot embossing fine structures, such as structures used for High Density Interconnects (HDIs).

It is a further object of this invention to provide a method of connecting a first array of microtool components to a first object, in a manner that they are aligned, with a high precision, with counterparts being a second array of microtool components on a second object.

In contrast to the prior art processes, for the first time a sintering method is applied for assembling microtool components to substrates, which serve as spacer plates and/or reinforcement of the microtool.

Preferably, the sintering method is a pressure sintering method.

A surprising insight underlying the invention is the fact that such a sintering or pressure sintering method provides a sufficiently reliable, strong, heat conducting and/or dimensionally stable connection, even for a hot embossing process, where at elevated temperatures, pressures of 10-300 bar and tensile forces of up to 100-200 bar may act upon the connection, and where a dimensional stability of down to the micrometer scale may be required.

According to a preferred embodiment, the forming temperature of a pressure sintered connection equals the working temperature of the tool. It has been found, that in a pressure sintering process, the parameters may be chosen in a manner that the heating needed for baking together metallic particles in the sintering process is achieved locally by friction when the pressure is applied. This makes possible that the forming temperature of the connection approximately equals the working temperature of the tool. The overall temperature during the sintering process may be as low as for example 150° C. to 600° C., sometimes even 150° C. to 250° C.

If the forming temperature approximately equals the working temperature of the tool, there are no such effects as thermal strain and bi-metal-effect deformations.

Especially, according to an embodiment of the invention, the temperature during the sintering process may be chosen to lie close to the working temperature of the microtool, for example for a HDI hot embossing process. It may more specifically lie within ±100° C. or even within ±50 or ±30° C. of the working temperature of the microtool. Therefore, according to this embodiment, the microtool is essentially strain-free at the working temperature. Moreover, if there is a bimetallic effect, the microtool essentially is in the non-deformed state at the working temperature.

The process further features the advantage that in addition to overcoming drawbacks of the prior art methods, the thermal contact between microtool component and object (substrate) is highly improved. This brings about important advantages. Special reference is in this context made to the International Patent Application PCT/CH02/00251, which is incorporated herein by reference.

A special embodiment of the invention comprises the manufacturing of embossing tools as arrays comprising a plurality of microtool components for producing HDIs (or similar products) as mass products: A plurality of microtool components may be placed in an array, using the sintering or pressure sintering method according to the invention, on an object or on an interconnected array of objects.

This special embodiment of the invention also includes a process of manufacturing a pair of tools each comprising an array of microtools, the pair of tools being for embossing a thin layer-like element from both sides. According to this embodiment, the corresponding microtools are fixed to their respective object (the press plate) in a manner that they are aligned, with a high precision, with their counterparts. This is preferably achieved by a process involving the steps of providing microtools with a self-aligning structure, loosely placing them on the object, aligning them using the self-aligning structure, fixing them to the object in a pre-fabricating step and then carrying out a sintering step according to the invention.

### BRIEF DESCRIPTION OF THE DRAWINGS

In the following, embodiments of the invention are described with reference to schematical drawings. The drawings show:

FIG. 1: Components of an embossing tool.

FIG. 2: A set-up for pressure sintering the embossing tool to the base plate.

FIG. 3: A set-up for pressure sintering a plurality of embossing tools to a base plate

FIGS. 3A, 3B. 3C, 3D: Further set-ups for pressure sintering a plurality of embossing tools to press plates.

FIGS. 4A and 4B: a pair of microtools comprising a self-aligning structure.

### DESCRIPTION OF THE PREFERRED EMBODIMENTS

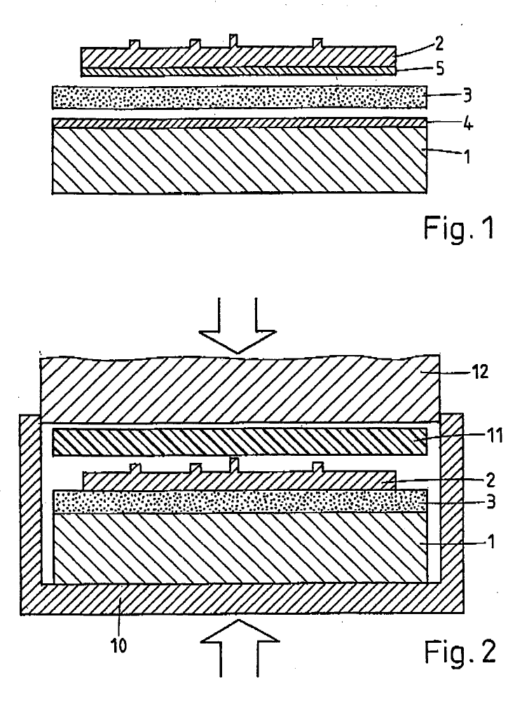

FIG. 1 shows base plate 1 of an embossing tool. The base plate 1 may be a steel sheet, preferably having a thickness between 0.1 mm and 2 mm, for example between 0.2 mm and 0.7 mm, or any other metal sheet, or any metal plate. It may also be made of a non-metallic material, for example a hard plastic. A microtool 2 is to be fastened to the base plate. The microtool may be of the kind described in the above mentioned international patent application publication WO 01/50825, for example a nickel tool or a nickel compound tool having a thickness of between 0.15 mm and 0.5 mm—or any other material composition having a structured surface. Concerning microtool materials for embossing tools, the reader is also referred to WO 01/50825 and the applications PCT/CH02/00250 and PCT/CH02/00251.

For fastening the microtool 2 to the base plate 1, a paste layer 3 is placed between base plate and microtool, for example by being applied to a surface of either of these components. As an alternative, paste material may be applied to both components. The paste comprises a powder like substance of a material that melts at a certain temperature well above room temperature, for example a silver powder or gold powder or an appropriate metal alloy powder. The paste layer 3 may further comprise ingredients allowing it to be completely dried or otherwise stiffened.

The thickness of the paste layer may be chosen to meet the demands of the particular set-up. It may be very thin—down to about 1 μm or less—or considerably thicker. It may, for example, have a thickness between 1 μm and 150 μm or 300 μm.

The sintering method according to the invention is now to sinter the microtool and the base plate together using the powder like or gravel like substance. This is done by treating the powder like substance in a manner that powder grains are welded together (are ‘baked together’, such that a dimensionally stiff sintered body is obtained) and the base plate 1 and the microtool are fastened to each other. This can be done by heating the paste layer (and as a consequence also the base plate and the microtool) to a the melting temperature of the powder like substance. As an alternative, this can be done by having ultrasonic vibrations impinge on the powder like material. As yet another alternative, this can be accomplished by a pressure sinterning method as hereinafter described using one embodiment as an example.

The base plate 1 or the microtool 2 or both optionally can have additional layers 4, 5, for example for providing a good bond between the respective components and the sintered body. For example, the additional layers may comprise silver or gold layers for being welded together with surfaces of the sintered body. Such additional layers are not necessary if the base plate or the microtool, respectively, are made of a material that itself is welded.

In the description of the following examples, the additional layers are left away for the sake of simplicity. However, all embodiments described hereinafter may have any number of such intermediate layers, and many preferred embodiments indeed will have such layers.

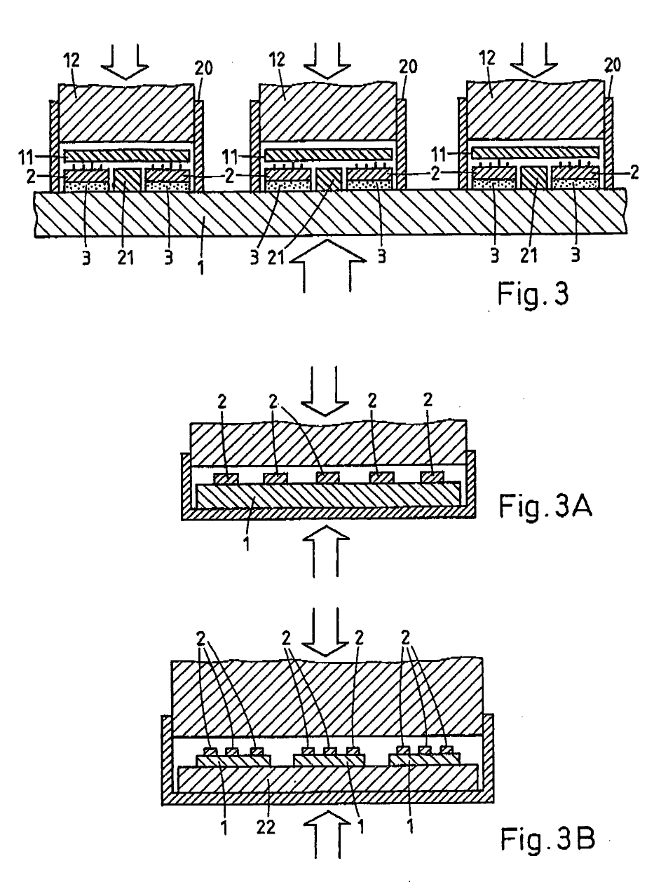

In FIG. 2, a pressure-resistant vessel 10 containing the base plate 1, the microtool 2 and the paste layer 3 is shown. A deformable body 11 is placed on top of the microtool 2. The deformable body 11 is made of a temperature resistant, elastically deformable material, such as silicone rubber or other elastically deformable material. It may, as an alternative, be a cushion-like element with a thin, highly bendable membrane wrapping and a fluid filling. In the shown example, it is disc-shaped, however, it can have other shapes. A press die 12 being a piston or the like is at least partially guided by the vessel 10 in a manner that the vessel 10, together with the press ram 12, forms a closed volume. As an alternative, if the press ram is not guided by the vessel walls, there may be sealing means which, together with the vessel and the press ram, create such a closed volume. The press die 12 and the vessel are connected to press means (not shown) for pressing the die and the vessel 12 against each other, as indicated by the arrows. Further bodies of the elastically deformable material or of another elastically deformable material may be present in the closed volume formed by vessel and press die. For example, there may be bodies of elastically deformable material more or less ‘filling up’ any free space in the closed volume.

The pressure sintering method includes the following steps:
a. The components shown in FIG. 2 (and possibly other components) are brought into their position.
b. As a next step, the paste layer 3 is dried, for example by being kept at an elevated temperature. By this, liquid constituents of the paste layer 3 evaporate, and the layer comprising the powder like material is dried. This drying process may be preceded by a degassing step at a somewhat lower temperature. The sequence of steps a. and b. may be exchanged. As an alternative, step b. may be left away, its effect being caused by the following step c.
c. The vessel 10 is heated up to a sintering temperature, for example 150° C. or more.
d. By the press means, a pressure is applied to the closed volume. It has been found that the elastically deformable material of the elastically deformable body 11 behaves “quasi-hydrostatically” in such a closed volume, and due to its presence the pressure is about equal everywhere in the closed volume. The pressure applied by press rams of the press means is for example 900 N/cm²(=90 bar) or higher, or, in a special embodiment, 1 kN/cm² or higher. It may be even in the range of 10 to 20 kN/cm². Due to the excerpted pressure, by local friction, elements of the powder like material are locally heated and welded together.
e. The base plate 1 with the microtool 2 pressure sintered onto it is taken out of the vessel. Further preparation steps, such as surface manipulating steps and/or a fastening of the base plate on a embossing press may follow.

Pressure sintering methods as such are known. U.S. Pat. No. 4,903,885 discloses a pressure sintering method with similar parameters, the disclosure of these process parameters (such as the applied pressure etc.) being incorporated herein by reference. However, the elements connected by pressure sintering are no tools but semiconductor components and semiconductor substrate.

If the tool components are of different materials—which they usually are—there may be, at the working temperature of the tool, a deformation due to a bimetallic effect—especially if it is a tool for hot embossing. This is because usually the manufacturing temperature and the working temperature of the tool are not equal. Such a deformation is often not acceptable.

DE 39 17 765 discloses a method for connecting objects having different thermal expansion coefficients. This method—relying on slightly curved press rams—provides some compensation of the bimetallic effect, however, it does not eliminate it. Further, it requires press rams to be adapted to the sintering temperature and to the working temperature of the objects to be joined.

According to a special embodiment of the invention, the bimetallic effect may be entirely eliminated for embossing tools. This is by choosing, in step, c. above, the sintering temperature to be the temperature, at which the embossing tool has its working temperature or a temperature near this temperature, as explained in the introductory part of this text.

As an alternative to applying the pressure quasi-hydrostatically, it may be applied hydrostatically by replacing the elastically deformable body by a fluid.

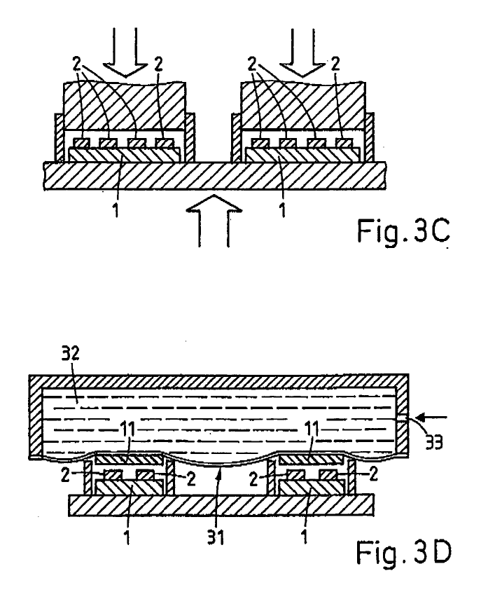

Now referring to FIG. 3, a method of fastening a plurality of microtools 2 on a base plate 1 using a pressure sintering method is explained. Closed volumes, each comprising one or a plurality of microtools are formed by the base plate, jacket elements 20 placed on the base plate 1, press dies 12, and appropriate sealing means (not shown). Inside the closed volumes, atop the microtools, deformable bodies 11 are placed. If a closed volume comprises more than one microtools, a space between the microtools may be filled by a further deformable member 21.

The process parameters of the pressure sintering process for fastening the microtools to the base plate may substantially as in the process described with reference to FIG. 2.

The different press dies 12 belong to one single press. Set-ups involving a plurality of presses, however, may be imagined.

Instead of a plurality of closed volumes, the set-up may alternatively be such that it comprises just one closed volume, as schematically shown in FIG. 3A. FIG. 3B shows a set-up involving a plurality of base plates 1 each with an array of microtools 2. The base plates are fixed to a carrier element 22. FIG. 3C, finally, shows a plurality of base plates 1, each with an array of microtools. Pressure sintering is done in a plurality of closed volumes. In FIG. 3. 3A through 3C, essential details such as the powder like material layer and the deformable element are left away in order to keep the drawings simple. Combinations of features of the set-ups of FIGS. 3 and 3A through 3C are possible, for example involving several base plates and a plurality of closed volumes for each base plate, or several closed volumes, each containing a plurality of base plates.

In the set-ups of FIGS. 3 and 3A-3C, the pressure excerpted on all microtools should be approximately equal. Since the elastically deformable material is almost not compressible, this does not come about automatically, but different heights of the microtools (or the like) may cause the pressure to be not equal. Therefore, according to special embodiments, the press may comprise pressure equating means. A very rough sketch of such pressure equating means is shown in FIG. 3D, where pressure is applied by means of a membrane 31 of a press. The membrane confines a press liquid volume 32, into which a press liquid, such as oil, may be pumped through an inlet 33 in order to create the necessary pressure.

As an alternative, to be incorporated in any one of the above embodiments, in addition to the elastically deformable material or instead of it, a body of a material having compressible and incompressible components/regions may be used—of example a sponge or foam. This will, among other things, cause the pressure between different regions—for example where the microtools have different heights—to be equated. Examples of such materials include any kind of foams/sponges, such as polyurethane foam sponges or any other, preferably weakly compressible, material of this kind.

Next, a method of fastening an array of microtools to a base plate for creating a pair of tools for embossing a thin layer-like element from both sides is disclosed. Embossing a thin layer-like element—such as a polymer foil—from both sides by an array of microtools may be used for mass production of arrays of HDIs with conductor structures—as mentioned above. Of course, this method may and often will be combined with the methods described with reference to any one of the above figures.

The manufacturing of such a pair of tools requires that the corresponding microtools of each tool of the pair of tools to be aligned with a high precision. Therefore, the following sequence of steps is applied:
a. Base plate and microtools of the pair of tools are placed at their approximate positions
b. Microtools are fine positioned in a manner that they are aligned with respect to each other
c. The microtools are provisionally fixed to the base plate in a pre-fabricating step
d. The microtools are pressure sintered to the base plate using a process as outlined above.

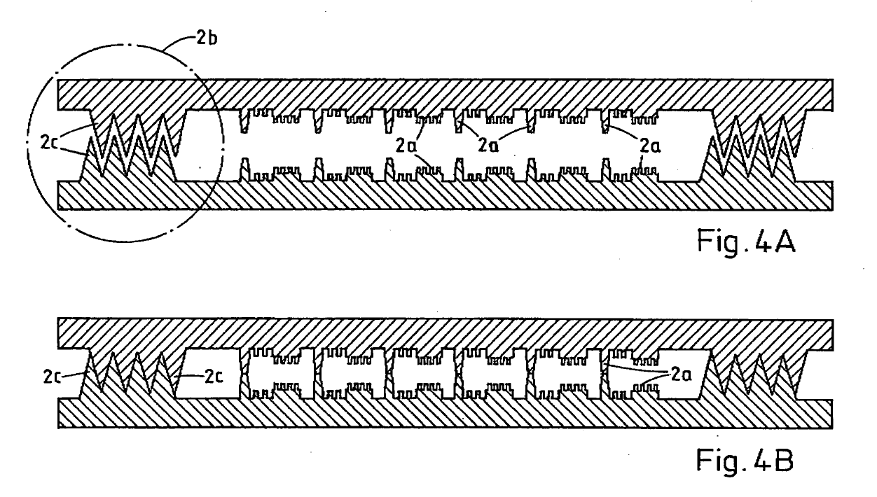

The fine positioning may be done by a self-aligning step. For this, the microtools comprise a self-aligning structure, as depicted in FIG. 4A. The microtools 2 shown comprise a central part having protrusions 2a for embossing structures in a substrate. In addition, for example in a peripheral part 2b, further protrusions 2c are present. There, the microtools comprise a regular array of sawtooth or pyramid or cone shaped (etc.) peaks or ridges which correspond to inverse structures on the corresponding other micro-tool. If both microtools are, coarsely aligned, put on top of each other, the structure engage in each other and cause a fine alignment (FIG. 4B). The thus aligned microtools may be placed between two base plates and provisionally fixed thereto, and a sintering object such as a metal powder paste is placed between the base plates and the respective microtools.

Instead of by an array of protrusions 2c, the alignment may also be accomplished by at least one single protrusion on one microtool with a corresponding inverse structure on the other microtool.

The provisional fixing may be a accomplished by different methods. As a first example, an underpressure between the microtools and the base plates may be caused by vacuum means. As an alternative, a paste like material comprising the powder material for the later sintering step may be placed between the microtools and the press plates, where the paste like material comprises at least one ingredient being an adhesive—for example an epoxy or an other adhesive. Further, the microtools may be spot welded to the base plate. To this end, either the base plate and/or the microtool may locally be deformed to be in direct contact with each other, or base plate and microtool are locally welded to each other through the paste like material (then, the powder particles are locally welded together to form a spot weld bond). Yet further alternatives include mechanical fixation methods such as, for example, the fixation by rivets etc.

Various other embodiments may be envisaged without departing from the spirit and scope of the invention.

The powder like material used for sintering does not have to be ingredient of a paste but may be in another form, for example in a powder form—held in place by appropriate mold means. It may also be form stable body of powder grains more or less loosely baked together.

Further, the invention is not restricted to hot embossing tools of a particular shape but refers to microtool components of arbitrary form or function and objects, to which they are fixed, of an arbitrary shape, dimensions or metal material.

1. A method for fastening a microtool to an object having a flat surface, said microtool comprising a first side with a plurality of protrusions and a second, essentially flat side, comprising the steps of:
placing a sintering object with a powder like substance between the flat surface of the object and the flat second side of the microtool, and
sintering the microtool component to the object.

2. The method as claimed in claim 1, wherein the microtool is pressure sintered to the object.

3. The method as claimed in claim 2, wherein during the pressure sintering, pressure is applied in one of quasi-hydrostatically or hydrostatically.

4. The method as claimed in claim 3 where elastically deformable material absorbs pressure on the microtool component having a structured surface.

5. The method as claimed in claim 2, comprising the further step of maintaining the temperature during sintering to satisfy the equation T_{E}−50°<T_{S}T_{E}<+50° wherein T_{E} is an embossing temperature and T_{S} is a sintering temperature of the microtool and the obiect and the sintering obiect, and wherein the microtool is for embossing structures in a substrate at the embossing Temperature T_{E}.

6. The method as claimed in claim 1, wherein the sintering object is a metal powder paste.

7. The method as claimed in claim 1, where an array of microtool components is fastened to an object or to an array of objects.

8. A method for fastening a pair of microtools to a pair of objects, the pair of microtools being for embossing structures into a substrate from two sides, the method comprising the steps of
assembling, for each microtool of the pair of microtools, the respective object, a sintering object and the microtool,
aligning the microtools of the pair of microtools with respect to each other,
provisionally fixing the microtools to the objects, and
sintering the mivrotools to the objects, wherein sintering includes the steps of:
providing a flat surface on each object,
providing each microtool with a first side with a plurality of protrusions and a second, essentially flat side,
placing the sintering obiect with a powder like substance between the flat surface of the object and the flat second side of the microtool, and
sintering the microtool component to the obiect.

9. The method as claimed in claim 8, wherein the microtool is provisionally fixed to the object using an ingredient of the sintering object, which serves as an adhesive.

10. The method as claimed in claim 8, wherein the microtool is provisionally fixed to the object by spot welding.

11. The method as claimed in claim 8, wherein the microtool is provisionally fixed to the object by mechanical fasteners. 12. A product produced by the method of claim 1.
